(19) United States
(12) Patent Application Publication
(10) Pub. No.: US 2025/0192515 A1
(43) Pub. Date: Jun. 12, 2025

(54) OPTICAL MODULE

(71) Applicant: Mitsubishi Electric Corporation, Tokyo (JP)

(72) Inventor: Junichi SUZUKI, Tokyo (JP)

(73) Assignee: Mitsubishi Electric Corporation, Tokyo (JP)

(21) Appl. No.: 18/845,276

(22) PCT Filed: Apr. 20, 2022
(86) PCT No.: PCT/JP2022/018238

§ 371 Date: Sep. 9, 2024

(51) Int. Cl. H01S 5/0683; H01S 5/00; H01S 5/02212; H01S 5/0231; H01S 5/024; H01S 5/0687; H04B 10/572

(52) U.S. Cl. CPC H01S 5/06837; H01S 5/0078; H01S 5/02212; H01S 5/0231; H01S 5/02415; H01S 5/0687; H04B 10/572

(57) ABSTRACT

An optical module includes a semiconductor laser, a first optical receiver receiving a laser beam from the semiconductor laser, an optical filter receiving the laser beam, and a second optical receiver receiving the laser beam via the optical filter, and a temperature adjuster adjusting a temperature in the semiconductor laser and a temperature in the optical monitor, and perform control to increase a temperature to be given to the semiconductor laser and the optical monitor when a wavelength monitor value Iλ/Ip being a ratio between an optical power monitor value Ip obtained by an output from the first optical receiver and a wavelength monitor value Iλ obtained by an output from the second optical receiver is larger than a wavelength set value, and change the temperature to be given to the semiconductor laser and the optical monitor when the wavelength monitor value Iλ/Ip deviates from the wavelength set value.

### TECHNICAL FIELD

The present disclosure relates to an optical module and a method of controlling the optical module, and particularly relates to an optical module including a single-wavelength semiconductor laser and a method of controlling the optical module.

### BACKGROUND ART

As a method for increasing the capacity of an optical communication system, there is a digital coherent communication method. The digital coherent communication method is a method of transmitting a large number of channels by placing a signal not only on the intensity but also on the phase of light. An interference phenomenon of light is used to extract phase information of light, and thus it is necessary to precisely control wavelengths of both a light source of a transmitter that transmits a signal and local light that is interference light in a receiver that receives the signal.

A single mode laser is used as these light sources.

The single mode laser oscillates at a single wavelength, but changes in oscillation wavelength and optical output intensity due to manufacturing errors and environmental temperatures.

Accordingly, a wavelength locker for wavelength control and a light intensity monitor are necessary in a light source module for digital coherent communication equipped with a single mode laser. In particular, the oscillation wavelength is required to be precisely controlled to 0.1 nm or less.

Patent Literature 1 discloses a laser module that locks a wavelength of a laser within a desired range.

The laser module disclosed in Patent Literature 1 compares a monitor output of a light receiving element that monitors light emitted from a rear end surface of a laser through a lens and a beam splitter with a monitor output of a light receiving element that has monitored light passing through an etalon, and locks a wavelength of the laser in a desired range by controlling temperatures of the first Peltier element and the second Peltier element.

In the laser module disclosed in Patent Literature 1, a laser, a third condenser lens, a first condenser lens, a beam splitter, two light receiving elements, and a thermistor are mounted on a mounting surface of a first Peltier element, and an etalon is mounted on a mounting surface of a second Peltier element.

### CITATION LIST

### Patent Literature

Patent Literature 1: JP 2003-69130 A

### SUMMARY OF INVENTION

### Technical Problem

In the laser module disclosed in Patent Literature 1, a Peltier element is provided in each of the laser and the etalon, and the number of components is large.

In addition, since the etalon is used, a component for collimating light incident on the etalon is required, and the size of the etalon itself is also required to some extent.

The present disclosure has been made in view of the above points, and an object of the present disclosure is to obtain an optical module that emits a single wavelength, and that has a small number of components and can be downsized.

### Solution to Problem

An optical module according to the present disclosure includes a semiconductor laser; an optical monitor including a first optical receiver to receive a laser beam from the semiconductor laser, an optical filter to receive the laser beam from the semiconductor laser, and a second optical receiver to receive the laser beam via the optical filter; and a temperature adjuster to adjust a temperature in the semiconductor laser and a temperature in the optical monitor, and to perform control, when a wavelength monitor value Iλ/Ip, which is a ratio between an optical power monitor value Ip obtained by an output from the first optical receiver and a wavelength monitor value Iλ obtained by an output from the second optical receiver, deviates from a wavelength set value, to change a temperature to be given to the semiconductor laser and the optical monitor.

### Advantageous Effects of Invention

According to the present disclosure, precise control can be performed for a single wavelength, the number of parts is small, and downsizing can be achieved.

### BRIEF DESCRIPTION OF DRAWINGS

FIG. 1 is a perspective view illustrating a state in which a cap is removed in an optical module according to a first embodiment.

FIG. 2 is a perspective view illustrating the optical module according to the first embodiment.

FIG. 3 is a cross-sectional view taken along line III-III of FIG. 1.

FIG. 4 is a block diagram illustrating an optical monitor in the optical module according to the first embodiment.

FIG. 5 is a schematic perspective view illustrating the optical monitor in the optical module according to the first embodiment.

FIG. 6 is a schematic block diagram illustrating an optical module device according to the first embodiment.

FIG. 7 is a diagram schematically illustrating temperature dependence of a wavelength in a semiconductor laser of the optical module according to the first embodiment.

FIG. 8 is a diagram schematically illustrating temperature dependence of a peak wavelength in an optical filter of the optical monitor of the optical module according to the first embodiment.

FIG. 9 is a diagram schematically describing a wavelength monitor value Iλ/Ip in the optical module according to the first embodiment.

FIG. 10 is a diagram illustrating a relationship between the wavelength monitor value Iλ/Ip and a wavelength λLD of a laser beam of the semiconductor laser in the optical module according to the first embodiment.

FIG. 11 is a diagram illustrating a relationship between the wavelength λLD of the laser beam of the semiconductor laser, a peak wavelength λfilt of an optical filter, and the wavelength monitor value Iλ/Ip in the optical module according to the first embodiment.

FIG. 12 is a diagram illustrating a relationship between a current value ILD of a driving current of the semiconductor laser and an optical power monitor value Ip in the optical module according to the first embodiment.

FIG. 13 is a diagram illustrating a relationship among a temperature, the optical power monitor value Ip, and the current value ILD of the driving current at points A to E in FIG. 12.

FIG. 14 is a diagram illustrating a target value λ_target of the wavelength λLD of the laser beam of the semiconductor laser and a target value Iλ_target of the wavelength monitor value Iλ/Ip in the optical module according to the first embodiment.

FIG. 15 is a flowchart illustrating an operation in the optical module according to the first embodiment.

FIG. 16 is a diagram illustrating another relationship among the wavelength λLD of the laser beam of the semiconductor laser, the peak wavelength λfilt of the optical filter, and the wavelength monitor value Iλ/Ip in the optical module according to the first embodiment.

FIG. 17 is a block diagram illustrating an optical monitor in an optical module according to a second embodiment.

FIG. 18 is a schematic perspective view illustrating an optical monitor in an optical module according to the second embodiment.

FIG. 19 is a cross-sectional view illustrating an optical module according to a third embodiment.

### DESCRIPTION OF EMBODIMENTS

### First Embodiment

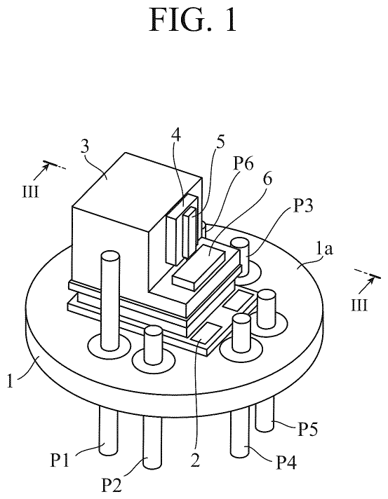

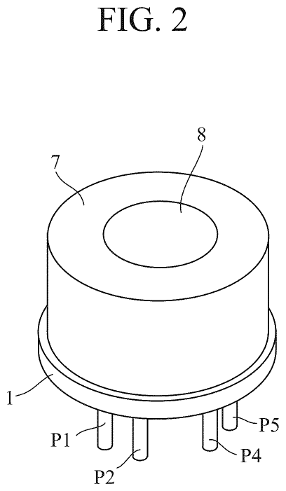

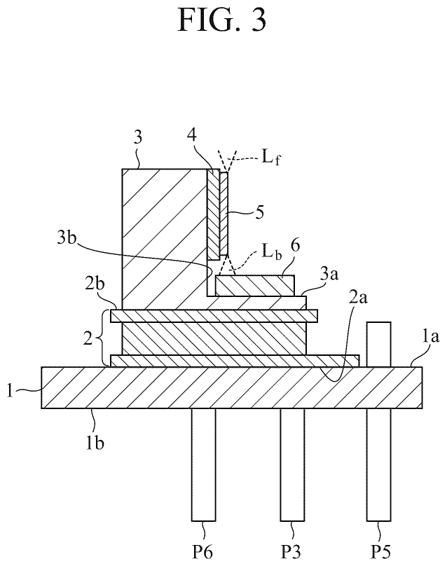

An optical module according to a first embodiment will be described with reference to FIGS. 1 to 16.

The optical module according to the first embodiment is preferable for use as a light source module for digital coherent communication.

The optical module according to the first embodiment is an example applied to a TO-CAN type optical transmission module for optical communication.

Therefore, a TO-CAN type optical transmission module for optical communication will be described below as an example.

As illustrated in FIGS. 1 to 3, the optical module according to the first embodiment includes a stem 1, a temperature adjuster 2, a base 3, a semiconductor laser submount (hereinafter, it is abbreviated as a submount) 4, a semiconductor laser 5, a planar waveguide optical monitor (hereinafter, it is abbreviated as an optical monitor) 6, a cap 7, a plurality of lead pins P1 to P6, and a grounding lead pin.

The stem 1 is formed by a disk-shaped metal. Note that the stem 1 is not limited to the disk shape, and may have a columnar shape or a quadrangular prismatic shape, and is only required to be a flat plate shape having an inner flat surface 1a and an outer flat surface 1b parallel to the inner flat surface 1a.

The inner flat surface 1a of the stem 1 is a mounting surface and is a region for component mounting.

The temperature adjuster 2 is mounted on the stem 1. The temperature adjuster 2 has a lower surface 2a that is a flat surface and an upper surface 2b that is a flat surface parallel to the lower surface 2a, the lower surface 2a is fixed to the inner flat surface 1a of the stem 1 with solder or a conductive adhesive, and the upper surface 2b serves as a mounting surface. Hereinafter, the upper surface 2b is referred to as a mounting surface.

The temperature adjuster 2 heats or cools the mounting surface 2b by a current flowing therethrough.

The temperature adjuster 2 adjusts the temperature of the semiconductor laser 5 and the temperature of the optical monitor 6.

The temperature adjuster 2 is a thermo-electric cooler (TEC) including a Peltier element.

The base 3 is an L-shaped metal member that is mounted on the mounting surface 2b of the temperature adjuster 2 and includes a flat surface portion 3a having upper and lower surfaces that are flat surfaces, and an elevation surface portion 3b formed integrally with the flat surface portion 3a and having an elevation surface that is a flat surface.

The lower surface of the flat surface portion 3a of the base 3 is fixed to the mounting surface 2b of the temperature adjuster 2 with solder or a conductive adhesive.

The semiconductor laser 5 is mounted and fixed on the elevation surface of the elevation surface portion 3b of the base 3 via the semiconductor laser submount 4.

The semiconductor laser 5 is fixed to the elevation surface of the elevation surface portion 3b of the base 3 in such a manner that an optical axis of a forward laser beam Lf and an optical axis of a backward laser beam Lb of the semiconductor laser 5 coincide with a central axis of the stem 1.

The submount 4 includes, for example, a substrate made of a dielectric of aluminum nitride (AlN) having a metal wiring layer patterned on the surface.

The optical monitor 6 is mounted and fixed on an upper surface of the flat surface portion 3a of the base 3.

The optical monitor 6 is fixed to the upper surface of the flat surface portion 3a of the base 3 so as to receive the backward laser beam Lb of the semiconductor laser 5.

The optical monitor 6 is disposed at an angle at which the backward laser beam Lb of the semiconductor laser 5 can be received.

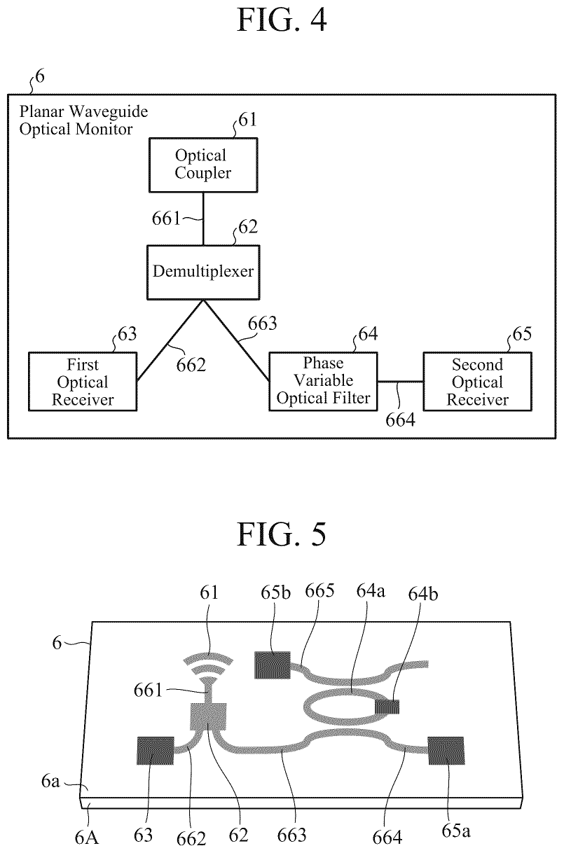

For example, when an angle at which maximum coupling efficiency of an optical coupler 61 (see FIGS. 4 and 5) in the optical monitor 6 with respect to the backward laser beam Lb of the semiconductor laser 5 can be obtained is 90 degrees with respect to a flat surface 6a of the optical monitor 6, the optical monitor 6 is disposed in a direction of 90 degrees, and when the angle is 80 degrees, the optical monitor 6 is disposed in a direction of 80 degrees.

When an angle of the optical monitor 6 with respect to the backward laser beam Lb of the semiconductor laser 5 is set to 90 degrees, an angle formed by the upper surface of the flat surface portion 3a of the base 3 and the elevation surface of the elevation surface portion 3b of the base 3 is set to 90 degrees.

In addition, when the angle of the optical monitor 6 with respect to the backward laser beam Lb of the semiconductor laser 5 is set to 80 degrees, the upper surface of the flat surface portion 3a of the base 3 may be inclined, and an angle formed by the upper surface of the flat surface portion 3a of the base 3 and the elevation surface of the elevation surface portion 3b of the base 3 may be set to 80 degrees.

The base 3 conducts heat on the mounting surface 2b of the temperature adjuster 2 to adjust the temperature of the semiconductor laser 5 through the submount 4, that is, to heat or cool the semiconductor laser 5.

At the same time, the base 3 conducts heat on the mounting surface 2b of the temperature adjuster 2 to adjust the temperature of the optical monitor 6, that is, to heat or cool the optical monitor.

Since the semiconductor laser 5 and the optical monitor 6 whose temperatures are adjusted by the temperature adjuster 2 are disposed in a vertical direction by the base 3, the area occupied by the semiconductor laser 5 and the optical monitor 6 on the mounting surface 2b of the temperature adjuster 2 can be reduced, and as a result, the temperature adjuster 2 can be downsized, and the optical module can be downsized.

The semiconductor laser 5 is a single-wavelength semiconductor laser, that is, a single mode laser oscillating at a single wavelength. As the single-wavelength semiconductor laser, for example, a distributed feedback (DFB) laser diode element (chip) or a distributed Bragg reflector (DBR) laser diode element (chip) is used.

The semiconductor laser 5 emits the forward laser beam Lf from the emission surface, and emits the backward laser beam Lb from the rear surface. The forward laser beam Lf is used for optical communication, and the backward laser beam Lb is monitored.

This type of single-wavelength semiconductor laser has the following characteristics. The intensity of light from the single-wavelength semiconductor laser changes due to the supplied driving current. Further, the intensity of light from the single-wavelength semiconductor laser also changes due to the temperature of the laser itself, and in general, the lower the temperature, the higher the optical output.

Furthermore, an oscillation wavelength of the laser beam from the single-wavelength semiconductor laser also changes due to the temperature in the laser. The oscillation wavelength of the laser beam from the single-wavelength semiconductor laser also changes due to Joule heat caused by the driving current.

Generally, when the temperature of the single-wavelength semiconductor laser increases, the oscillation wavelength of the laser beam from the single-wavelength semiconductor laser shifts to the longer wavelength side.

That is, the wavelength of the laser beam oscillated from the single-wavelength semiconductor laser has temperature dependence. The temperature dependence of the wavelength in the single-wavelength semiconductor laser is, for example, 90 pm/° C., and as illustrated in FIG. 7, the wavelength increases by 90 pm every time the temperature in the single-wavelength semiconductor laser increases by +1° C., and increases by 270 pm every time the temperature increases by +3° C.

FIG. 7 schematically illustrates the temperature dependence of the wavelength in the semiconductor laser 5, where the horizontal axis represents an increase amount with respect to the temperature of the wavelength λLD, and the vertical axis represents an optical output obtained by monitoring the backward laser beam Lb of the semiconductor laser 5, that is, an optical power monitor value Ip indicating the light intensity as a current value.

In short, the wavelength of the laser beam oscillated in the semiconductor laser 5 has temperature dependence, and the temperature is adjusted by the temperature adjuster 2 in order to maintain the wavelength of the laser beam constant.

The optical monitor 6 measures the light intensity of the backward laser beam Lb from the semiconductor laser 5, obtains an optical power monitor value Ip including a current value for controlling a value of a driving current to the semiconductor laser 5 in such a manner that the optical output of the semiconductor laser 5 becomes a target value, and obtains a wavelength monitor value Iλ including a current value used for controlling a value of a current to be supplied to the temperature adjuster 2 in such a manner that the wavelength of the laser beam from the semiconductor laser 5 becomes a target value.

The optical monitor 6 constitutes a part of a wavelength locker for wavelength control of laser beam from the semiconductor laser 5.

The temperature adjuster 2 performs control to heat the mounting surface 2b in accordance with the value of the current to be supplied to increase the temperature to be given to the semiconductor laser 5 and the optical monitor 6 when the optical power monitor value Ip is larger than a current set value, and cool the mounting surface 2b in accordance with the value of the current to be supplied to decrease the temperature to be given to the semiconductor laser 5 and the optical monitor 6 when the optical power monitor value Ip is smaller than the current set value.

The current set value is set to, for example, ±10% of a target value Ip_target of the optical power monitor value Ip when the optical output of the semiconductor laser 5, that is, the driving current at which the light intensity becomes the target value is supplied to the semiconductor laser 5.

When a wavelength monitor value Iλ/Ip, which is a ratio between the optical power monitor value Ip and the wavelength monitor value IN, deviates from a wavelength set value, the temperature adjuster 2 changes the temperature of the mounting surface 2b in accordance with the value of the supplied current, and changes the temperature to be given to the semiconductor laser 5 and the optical monitor 6.

In the present example, the temperature adjuster 2 performs control to heat the mounting surface 2b in accordance with the value of the current to be supplied to increase the temperature to be given to the semiconductor laser 5 and the optical monitor 6 when the wavelength monitor value Iλ/Ip is larger than the wavelength set value, and cool the mounting surface 2b in accordance with the value of the current to be supplied to decrease the temperature to be given to the semiconductor laser 5 and the optical monitor 6 when the wavelength monitor value Iλ/Ip is smaller than the wavelength set value.

For example, the wavelength setting value is set to +10% of the target value Iλ_target of the wavelength monitor value Iλ/Ip when the wavelength λLD of the laser beam of the semiconductor laser 5 is set to the target value λ_target.

As illustrated in FIGS. 4 and 5, the optical monitor 6 includes an optical coupler 61, a demultiplexer 62, a first optical receiver 63, an optical filter 64, a second optical receiver 65, and optical waveguides 661 to 665.

The optical monitor 6 is, for example, a planar waveguide optical monitor using a silicon photonics chip formed by integrating the optical coupler 61, the demultiplexer 62, the first optical receiver 63, the optical filter 64, the second optical receiver 65, and the optical waveguides 661 to 665 on a flat surface of a silicon (Si) substrate 6A.

The optical waveguides 661 to 665 are silicon waveguides made of silicon.

The optical coupler 61 receives the backward laser beam Lb from the semiconductor laser 5 and couples the backward laser beam Lb incident perpendicularly to the flat surface 6a of the optical monitor 6 to the optical waveguide 661.

The optical coupler 61 is, for example, a grating coupler. Since the grating coupler has a function of coupling the backward laser beam Lb from the semiconductor laser 5 coming from above the flat surface 6a of the optical monitor 6 to the optical waveguide 661, the flat surface 6a of the optical monitor 6 and the laser 5 are arranged by the base 3 at an angle at which the maximum coupling efficiency of the grating coupler can be obtained.

Note that the optical coupler 61 may be an elephant coupler.

The grating coupler can increase the mode of light and hence has a feature of having smaller position dependence than that of end surface coupling of waveguides, and thus the grating coupler is preferable for the optical coupler 61 of this example.

The demultiplexer 62 demultiplexes the backward laser beam Lb received by the optical coupler 61 and transmitted from the semiconductor laser 5 via the optical waveguide 661 into two laser beams.

The demultiplexer 62 is, for example, any of a directional coupler, a multi-mode interferometer (MMI), or a Y-branch waveguide. In this example, MMI is used as the demultiplexer 62.

The first optical receiver 63 receives the backward laser beam Lb from the semiconductor laser 5 by the optical coupler 61, receives one laser beam demultiplexed from the demultiplexer 62 via the optical waveguide 662, performs photoelectric conversion, and outputs a current corresponding to the backward laser beam Lb from the semiconductor laser 5.

The first optical receiver 63 directly converts the backward laser beam Lb obtained by coupling the backward laser beam Lb from the semiconductor laser 5 by the optical coupler 61 into a current, thus functions as an optical power monitor of the semiconductor laser 5.

That is, the current value Ip of the current obtained from the first optical receiver 63 is the optical power monitor value Ip indicating the optical output of the laser beam from the semiconductor laser 5, that is, the light intensity by the current value.

The first optical receiver 63 is a waveguide optical receiver or a surface incident optical receiver, and in this example, a photodiode which is a silicon germanium (SiGe) optical receiver is used.

The optical filter 64 receives the backward laser beam Lb from the semiconductor laser 5 by the optical coupler 61, and receives the other laser beam demultiplexed by the demultiplexer 62 via the optical waveguide 663.

The optical filter 64 is a phase variable optical filter having temperature dependence of a wavelength.

That is, a value of a peak of the wavelength of the laser beam output from the optical filter 64 has temperature dependence that shifts to the longer wavelength side as the temperature in the optical filter 64 increases.

The optical filter 64 is a ring resonator 64a, and in this example, the ring resonator 64a is used as a filter having a periodic characteristic.

Note that the optical filter 64 is not limited to the ring resonator filter.

Ideally, a filter having no temperature dependence is preferable as the optical filter 64.

However, in general, the temperature dependence is difficult to become 0, and the filter may be a filter having temperature dependence that shifts to a long wavelength side as the temperature increases, or a filter having temperature dependence that shifts to a short wavelength side as the temperature increases.

Instead of the ring resonator filter, a Mach-Zehnder interferometer (MZ interferometer) or a distributed Bragg reflector (DBR) filter may be used.

In this example, the ring resonator 64a is used as the optical filter 64, and hereinafter, the ring resonator 64a is referred to as a ring resonator filter.

The ring resonator filter 64a is constituted by an optical waveguide forming a closed loop. The optical waveguide 663 connected to the other output end of the demultiplexer 62 is defined as an input side, the optical waveguide 664 connected to an input end of the second optical receiver 65 is defined as an output side, and the optical waveguide forming the closed loop constituting the ring resonator filter 64a is coupled with the optical waveguide 663 of the input side and the optical waveguide 664 of the output side to generate resonance in the optical waveguide forming the closed loop, thereby functioning as a filter.

Note that the optical waveguide 665 on the output side is also coupled.

The optical waveguide forming the closed loop is a silicon waveguide made of silicon.

Since the optical waveguide forming the closed loop can have a diameter of about 100 μm, the etalon used as an optical filter for a wavelength locker is very small as compared with a rectangular parallelepiped having a side of about 1 mm as disclosed in Patent Literature 1, the optical waveguide can be downsized, and influence of a temperature gradient due to the environmental temperature of the ring resonator filter 64a can be suppressed.

As the second optical receiver 65, one of a photodiode 65a that is connected, that is, coupled to the ring resonator filter 64a via the optical waveguide 664 and receives transmitted light from the ring resonator filter 64a and a photodiode 65b that is connected, that is, coupled to the ring resonator filter 64a via the optical waveguide 665 and receives transmitted light from the ring resonator filter 64a is used.

As is generally known, since the optical waveguide 664 and the optical waveguide 665 are arranged to face the ring resonator filter 64a, intensity with respect to a phase of a current flowing through the photodiode 65b connected to a through port of the optical waveguide 664 exhibits a characteristic inverted with respect to intensity with respect to a phase of a current flowing through the photodiode 65a connected to a drop port of the optical waveguide 665.

That is, the intensity of the current flowing through the photodiode 65a and the photodiode 65b with respect to the phase is inverted from 1 to 0 and from 0 to 1 every 2π, and when the intensity with respect to the phase of the current flowing through the photodiode 65a indicates 1, the intensity with respect to the phase of the current flowing through the photodiode 65b indicates 0. Conversely, when the intensity with respect to the phase of the current flowing through the photodiode 65a indicates 0, the intensity with respect to the phase of the current flowing through the photodiode 65b indicates 1.

In short, a gradient of the intensity of the current flowing through the photodiode 65a is similar to the gradient of the intensity of the current flowing through the photodiode 65b.

Therefore, the photodiode 65a may be used as the second optical receiver 65.

The output from the second optical receiver 65 is obtained by converting a laser beam obtained by filtering the backward laser beam Lb obtained by coupling the backward laser beam Lb from the semiconductor laser 5 by the optical coupler 61 by the ring resonator filter 64a, in this example, the laser beam resonated with the backward laser beam Lb into a current, and thus, when the wavelength of the backward laser beam Lb changes, the current value from the second optical receiver 65 also changes in accordance with the wavelength dependence of the ring resonator filter 64a.

Therefore, the current value Iλ of the current obtained from the second optical receiver 65 can be used as the wavelength monitor value Iλ used to obtain the wavelength monitor value Iλ/Ip of the semiconductor laser 5, and the ring resonator filter 64a and the second optical receiver 65 function as a wavelength monitor of the semiconductor laser 5.

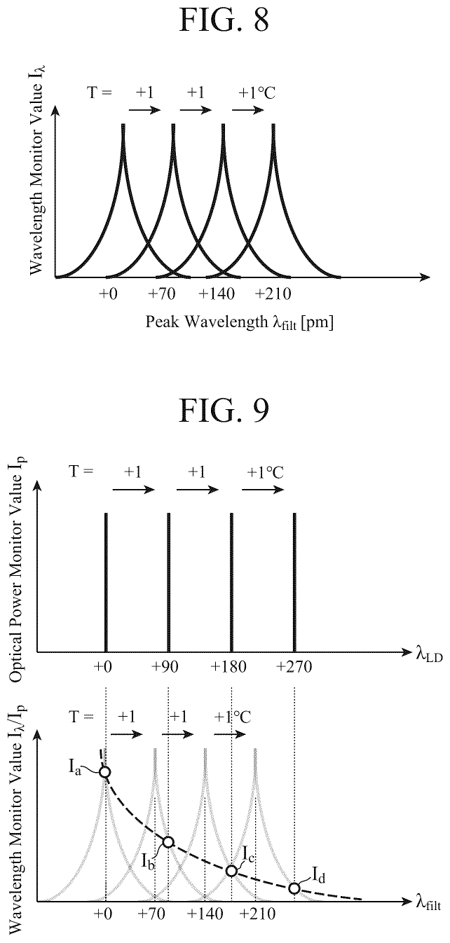

The temperature dependence of the peak value of the wavelength in the ring resonator filter 64a is, for example, 70 pm/° C., and as illustrated in FIG. 8, the wavelength increases by 70 pm every time the temperature in the ring resonator filter 64a increases by +1° C., and increases by 210 pm every time the temperature increases by +3° C.

FIG. 8 schematically illustrates the temperature dependence of the peak value of the wavelength in the ring resonator filter 64a, where the horizontal axis represents an increase amount with respect to the temperature of the peak wavelength λfilt, and the vertical axis is the wavelength monitor value Iλ indicating the optical output, that is, the light intensity from the ring resonator filter 64a for monitoring the wavelength of the backward laser beam Lb of the semiconductor laser 5 by the current value.

The wavelength monitor value IN, that is, the current value Iλ obtained from the second optical receiver 65 changes not only in the wavelength of the backward laser beam Lb of the semiconductor laser 5 but also in the light intensity of the backward laser beam Lb.

Therefore, by dividing the wavelength monitor value Iλ by the optical power monitor value Ip, the wavelength monitor value Iλ/Ip based only on the wavelength of the backward laser beam Lb is obtained.

The wavelength monitor value Iλ/Ip will be schematically described with reference to FIG. 9. FIG. 9 is a diagram in which a diagram illustrating the temperature dependence of the wavelength in the semiconductor laser 5 illustrated in FIG. 7 and a diagram illustrating the temperature dependence of the peak value of the wavelength in the ring resonator filter 64a illustrated in FIG. 8 are vertically juxtaposed.

Temperatures of the semiconductor laser 5 and the optical monitor 6 are regulated by heat on the mounting surface 2b of the temperature adjuster 2 via the base 3, a temperature rise in the semiconductor laser 5 and a temperature rise in the optical monitor 6 are the same.

Therefore, every time the temperatures in the semiconductor laser 5 and the ring resonator filter 64a increase by +1° C., the wavelength monitor value Iλ/Ip changes as Ib, Ic, and Id in order from Ia indicated by a circle in FIG. 9.

The wavelength monitor value Iλ/Ip changes from Ia to Ib, Ic, and Id in this order due to that the temperature dependence of the wavelength in the semiconductor laser 5 is 90 pm/° C., the temperature dependence of the peak value of the wavelength in the ring resonator filter 64a is 70 pm/° C., and the temperature dependences are different to each other.

In this example, by increasing the temperature with respect to the wavelength λLD of the laser beam of the semiconductor laser 5, the wavelength monitor value Iλ/Ip has a downward gradient.

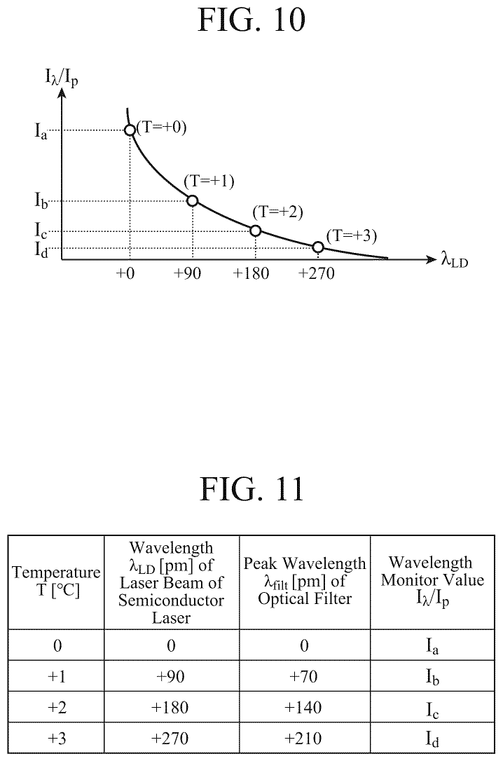

FIG. 10 is a diagram obtained by extracting the relationship between the wavelength monitor value Iλ/Ip illustrated in FIG. 9 and the wavelength λLD of the backward laser beam Lb of the semiconductor laser 5.

In FIG. 10, the horizontal axis represents the wavelength λLD of the laser beam of the semiconductor laser 5, and the vertical axis represents the wavelength monitor value Iλ/Ip.

As is clear from FIG. 10, it can be seen that a characteristic illustrated in FIG. 10 has a shape obtained by extending the characteristic of the ring resonator filter 64a when each temperature is constant horizontally in the drawing, and at the same time, it can be confirmed that the wavelength monitor value Iλ/Ip has straightforward wavelength dependence when the temperature changes.

That is, the wavelength monitor value Iλ/Ip indicates a value of Ia when the temperature T is +0, that is, the temperature in the semiconductor laser 5 and the temperature in the optical monitor 6 are set to temperatures before being changed, the wavelength monitor value Iλ/Ip indicates a value of Ib when the temperature is increased by +1 degree, the wavelength monitor value Iλ/Ip indicates a value of Ic when the temperature is increased by +2 degrees, and the wavelength monitor value Iλ/Ip indicates a value of Id when the temperature is increased by +3 degrees.

On the other hand, the wavelength λLD of the backward laser beam Lb indicates a wavelength λLD when the increment is 0, that is, the temperature in the semiconductor laser 5 and the temperature in the optical monitor 6 are set to be temperatures before being changed when the wavelength monitor value Iλ/Ip indicates a value of Ia, the wavelength λLD of the backward laser beam Lb indicates that it is increased by +90 pm when the wavelength monitor value Iλ/Ip indicates a value of Ib, the wavelength λLD of the backward laser beam Lb indicates that it is increased by +180 pm when the wavelength monitor value Iλ/Ip indicates a value of Ic, and the wavelength λLD of the backward laser beam Lb indicates that it is increased by +270 pm when the wavelength monitor value Iλ/Ip indicates a value of Id.

In short, the wavelength monitor value Iλ/Ip indicates wavelength dependence by the wavelength of the laser beam, and it is possible to know a wavelength shift in the laser beam of the semiconductor laser 5 by knowing the wavelength monitor value Iλ/Ip.

Therefore, by adjusting the temperature of the semiconductor laser 5, the wavelength of the laser beam of the semiconductor laser 5 can be adjusted, and precise control can be performed with respect to a single wavelength of the laser beam of the semiconductor laser 5.

Note that FIG. 11 illustrates the relationship illustrated in FIG. 10 as a table.

In the present example, in the optical filter 64, the phase modulator 64b is further disposed on the optical waveguide forming a closed loop constituting the ring resonator filter 64a. The phase modulator 64b is, for example, a heater.

The position of the peak wavelength λfilt by the ring resonator filter 64a, that is, the position of the peak of the current value Iλ obtained from the second optical receiver 65 generally has an individual difference due to a manufacturing error of the ring resonator filter 64a.

The phase modulator 64b controls the ring resonator filter 64a, that is, adjusts the position of the peak wavelength λfilt by the ring resonator filter 64a.

That is, in order to obtain the current value Iλ obtained from the second optical receiver 65 for obtaining the target value Iλ_target of the wavelength monitor value Iλ/Ip with respect to the target value λ_target of the wavelength λLD of the laser beam of the semiconductor laser 5, the position of the peak wavelength λfilt by the ring resonator filter 64a is adjusted by the phase modulator 64b.

For example, when the target value Iλ_target is at the position of the wavelength monitor value Iλ/Ip=0, even if the wavelength λLD of the laser beam of the semiconductor laser 5 changes, the value of the wavelength monitor value Iλ/Ip hardly changes, and the control of the ring resonator filter 64a cannot be performed well.

In order to avoid this, the temperature in the ring resonator filter 64a is adjusted by the phase modulator 64b in such a manner that the target value Iλ_target becomes a value of the wavelength monitor value Iλ/Ip suitable for control.

The value of the wavelength monitor value Iλ/Ip suitable for control of the ring resonator filter 64a is around a median value of the wavelength monitor value Iλ/Ip, and in a region where the gradient of the wavelength dependence is large, in this example, the wavelength monitor value Iλ/Ip illustrated in FIG. 10 determines Ib as the target value Iλ_target by adjusting the temperature in the ring resonator filter 64a by the phase modulator 64b.

The phase modulator 64b is not limited to the heater as long as it can change a resonance wavelength of the ring resonator filter 64a, and may be a phase changer such as injection of a current or drawing of a current by a pn junction, a quantum confinement Stark effect by application of a voltage, or a Pockels effect.

As described above, in the first embodiment, the ring resonator with the phase adjuster is used as the optical filter 64.

Note that, in a case where manufacturing accuracy of the ring resonator filter 64a is improved or the position of the peak wavelength of the ring resonator filter 64a can be set without operation by external power by a post-process such as trimming, the phase modulator 64b is unnecessary, and only the ring resonator filter 64a may be used as the optical filter 64.

Note that the optical monitor 6 may be a planar waveguide optical monitor in which the optical coupler 61, the demultiplexer 62, the first optical receiver 63, the optical filter 64, the second optical receiver 65, and the optical waveguides 661 to 665 are integrated on a flat surface of an indium phosphide (InP) substrate 6A that is a compound semiconductor.

In addition, the optical coupler 61, the demultiplexer 62, the first optical receiver 63, the optical filter 64, the second optical receiver 65, and the optical waveguides 661 to 665 are not necessarily integrated, and individual components may be modularized.

The optical receivers 13 and 14 may be InP optical receivers.

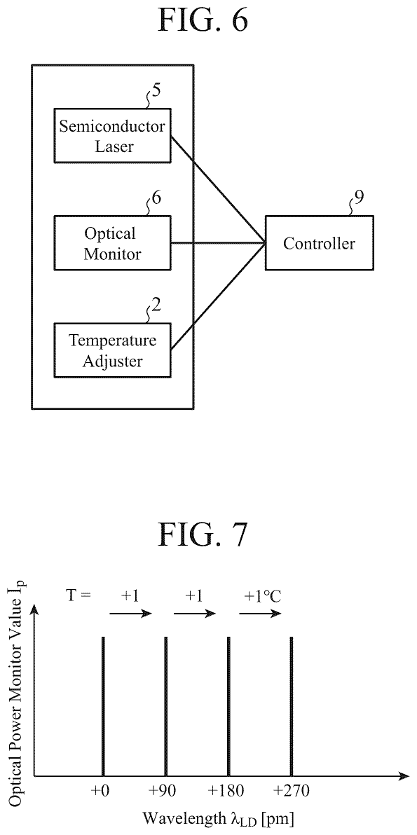

As illustrated in FIG. 6, the temperature adjuster 2, the semiconductor laser 5, and the optical monitor 6 are controlled by the controller 9.

The controller 9 exchanges signals with the semiconductor laser 5, the optical monitor 6, and the temperature adjuster 2, and controls the current and voltage to each of the semiconductor laser 5, the optical monitor 6, and the temperature adjuster 2 to control the light intensity of the laser beam from the semiconductor laser 5 and the wavelength of the laser beam.

The controller 9 controls the driving current to the semiconductor laser 5 in such a manner that the optical power monitor value Ip from the first optical receiver 63 of the optical monitor 6 is input to the semiconductor laser 5, and the optical power monitor value Ip falls within a range of ±10% of the target value Ip_target of the optical power monitor value that is a current set value.

The controller 9 controls the current supplied to the temperature adjuster 2 in such a manner that the optical power monitor value Ip from the first optical receiver 63 of the optical monitor 6 falls within a range of the current set value of ±10% of the target value Ip_target of the optical power monitor value with respect to the temperature adjuster 2.

The controller 9 supplies a current for heating the mounting surface 2b of the temperature adjuster 2 to the temperature adjuster 2 when the optical power monitor value Ip is larger than the current set value, and supplies a current for cooling the mounting surface 2b of the temperature adjuster 2 to the temperature adjuster 2 when the optical power monitor value Ip is smaller than the current set value.

Further, the controller 9 receives the optical power monitor value Ip from the first optical receiver 63 of the optical monitor 6 and the wavelength monitor value Iλ from the second optical receiver 65 of the optical monitor 6, calculates the wavelength monitor value Iλ/Ip from the received optical power monitor value Ip and the wavelength monitor value Iλ, and controls the current supplied to the temperature adjuster 2 in such manner that the wavelength monitor value Iλ/Ip falls within a range of a wavelength set value of +10% of a target value Iλ_target of the wavelength monitor value Iλ/Ip when the wavelength λLD of the laser beam of the semiconductor laser 5 is set to the target value λ_target.

When the wavelength monitor value Iλ/Ip deviates from the wavelength set value, the controller 9 supplies a current for changing the temperature of the mounting surface 2b to the temperature adjuster 2.

In the present example, when the wavelength monitor value Iλ/Ip is larger than the wavelength set value, the controller 9 supplies a current for heating the mounting surface 2b of the temperature adjuster 2 to the temperature adjuster 2, and when the wavelength monitor value Iλ/Ip is smaller than the wavelength set value, the controller 9 supplies a current for cooling the mounting surface 2b of the temperature adjuster 2 to the temperature adjuster 2.

The controller 9 supplies, to the phase modulator 64b in the optical filter 64, a current of a target value Ih_target at the time of obtaining the optical output of the laser beam in which the light intensity of the laser beam of the semiconductor laser 5 becomes the target value and the wavelength λLD of the laser beam of the semiconductor laser 5 becomes the target value λ_target.

The controller 9 and the optical monitor 6 constitute a wavelength locker for wavelength control of the laser beam from the semiconductor laser 5.

The optical module and the controller 9 constitute an optical module device.

The semiconductor laser 5, the optical monitor 6, and the temperature adjuster 2 are electrically connected to the lead pins P1 to P6 by wires (not illustrated) such as gold wires by wire bonding in order to exchange signals with the controller 9.

Each of the lead pins P1 to P6 penetrates each of the through holes of the stem 1, and is fixed to the stem 1 by sealing glass filled and solidified between the lead pins P1 to P6 and the through holes. The sealing glass electrically insulates each of the lead pins P1 to P6 from the stem 1 and maintains airtightness.

Connection of inner lead parts of the lead pins P1 to P6 exposed from the inner flat surface of the stem 1 is, for example, as follows.

The lead pin P1 is connected to one electrode of the semiconductor laser 5, and transmits the driving current from the controller 9 to the semiconductor laser 5. The lead pin P1 is a main signal lead pin for the semiconductor laser 5.

The lead pin P2 is connected to the first optical receiver 63 of the optical monitor 6, and transmits a current indicating the optical power monitor value Ip from the first optical receiver 63 to the controller 9. The lead pin P2 is a first monitor lead pin for the optical monitor 6.

The lead pin P3 is connected to the second optical receiver 65 of the optical monitor 6, and transmits a current indicating the wavelength monitor value Iλ from the second optical receiver 65 to the controller 9. The lead pin P3 is a second monitor lead pin for the optical monitor 6.

The lead pin P4 and the lead pin P5 are connected to a pair of electrodes in the temperature adjuster 2, and transmit a current supplied from the controller 9 to the temperature adjuster 2. The lead pins P4 and P5 are a pair of temperature control lead pins for the temperature adjuster 2.

The lead pin P6 is connected to the phase modulator 64b disposed on the optical filter 64 in the optical monitor 6, and transmits the current supplied from the controller 9 to the phase modulator 64b. The lead pin P6 is a phase adjustment lead pin for the phase modulator 64b.

Further, the stem 1 has a grounding lead pin (not illustrated) having one end fixed to the outer surface of the stem 1 by welding or brazing. The grounding lead pin is for setting the stem 1 to a ground potential, and is an electrically grounded grounding ground pin.

The optical module according the first embodiment only needs to include a total of seven lead pins including six signal lead pins P1 to P6 and one grounding lead pin, and the optical module can be configured with a small number of lead pins.

The cap 7 is a lens cap made by metal, having a bottomed portion and a side wall portion with one end opened, and formed by cylindrical metal having an outer diameter slightly smaller than a diameter of the stem 1. At the center of the bottomed portion of the cap 7, an opening on which flat glass or a lens as a window 8 is mounted is formed. The flat glass or lens that is the window 8 is attached to the opening formed in the bottomed portion by bonding with an adhesive or melting in such a manner that airtightness is maintained inside and outside the cap.

An end surface of the side wall portion of the cap 7 comes into contact with the peripheral end portion of the inner flat surface of the stem 1 and is joined and fixed by electric welding. The inside surrounded by the stem 1 and the cap 7 is filled with an inert gas or brought into a vacuum state, and is hermetically sealed by blocking the semiconductor laser 5 from the outside air.

The forward laser beam Lf from the semiconductor laser 5 is emitted from the window 8.

The stem 1 and the cap 7 constitute a TO-CAN type package.

Next, an operation of the optical module according to the first embodiment will be described.

The optical module is a module on which the semiconductor laser 5, which is a laser chip that has been confirmed to obtain an optical output equal to or higher than a target within an operating temperature range and to obtain a target oscillation wavelength within a controllable temperature range, is mounted.

First, as a preliminary preparation for operating the optical module, the following is performed.

A target value ILD_target of the driving current to be supplied to the semiconductor laser 5, a target value ITEC_target of the current to be supplied to the temperature adjuster 2, and the target value Ih_target of the current to be supplied to the phase modulator 64b, when the optical output in which the wavelength λLD becomes the target value λ_target and the light intensity becomes the target value Ip_target of the optical power monitor value Ip, are acquired from the semiconductor laser 5.

These target values are acquired using a generally known light intensity measuring device and light wavelength measuring device.

Further, at the same timing, the target value Ip_target of the optical power monitor value Ip, the target value Iλ_target of the wavelength monitor value Iλ/Ip when the wavelength λLD is the target value λ_target, and the wavelength dependence of the wavelength monitor value Iλ/Ip around the target value Iλ_target, when the target value Ip_target of the optical power monitor value Ip at which the light intensity becomes the target value and the optical output in which the wavelength λLD becomes the target value λ_target are obtained, are acquired from the semiconductor laser 5.

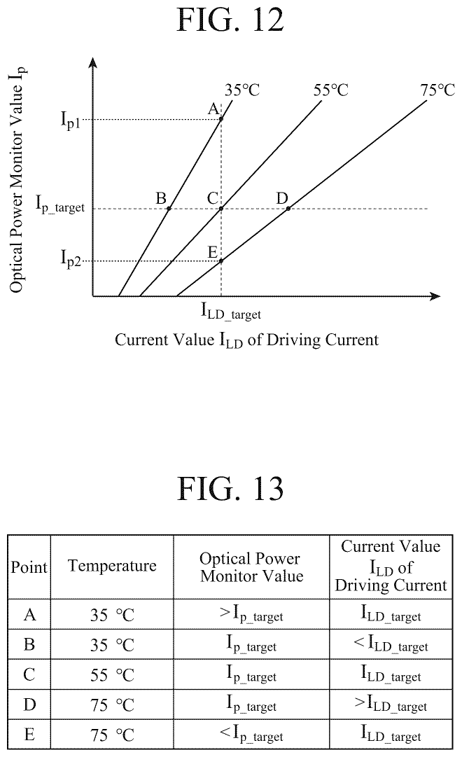

As illustrated in FIG. 12, in the semiconductor laser 5, the current value ILD of the driving current and the optical power monitor value Ip are in a proportional relationship, and as the temperature of the semiconductor laser 5 is lower, the optical output increases, that is, the optical power monitor value Ip increases.

In the present example, a case will be described in which the driving current of the target value ILD_target is supplied to the semiconductor laser 5, and when the temperature in the semiconductor laser 5 is 55° C., an optical output in which the wavelength λLD becomes the target value λ_target and the light intensity becomes the target value Ip_target of the optical power monitor value Ip is obtained.

This is the position of the point C illustrated in FIG. 12.

In FIG. 12, the horizontal axis represents the current value ILD of the driving current, and the vertical axis represents the optical power monitor value Ip. The relationship between the current value ILD of the driving current and the optical power monitor value Ip is illustrated, in which a straight line of 35° C. is a temperature of 35° C. in the semiconductor laser 5, a straight line of 55° C. is a temperature of 55° C. in the semiconductor laser 5, and a straight line of 75° C. is a temperature of 75° C. in the semiconductor laser 5.

FIG. 13 illustrates a relationship among the optical power monitor value Ip, the current value ILD of the driving current, and the temperature at points A to E in FIG. 12.

The position of the point C indicates a position at a temperature of 55° C. at which an optical output in which the target value Ip_target of the optical power monitor value Ip and the wavelength λLD become the target value λ_target is obtained.

The position of the point A indicates a position at a temperature of 35 degrees when the wavelength λLD is the target value λ_target and the optical power monitor value Ip exceeds the target value Ip_target.

The position of the point B indicates a position at a temperature of 35 degrees when the optical power monitor value Ip is the target value Ip_target and the wavelength λLD exceeds the target value λ_target.

The position of the point D indicates a position at a temperature of 75 degrees when the optical power monitor value Ip is the target value Ip_target and the wavelength λLD exceeds the target value λ_target.

The position of the point E indicates a position at a temperature of 75 degrees when the wavelength λLD is the target value λ_target and the optical power monitor value Ip exceeds the target value Ip_target.

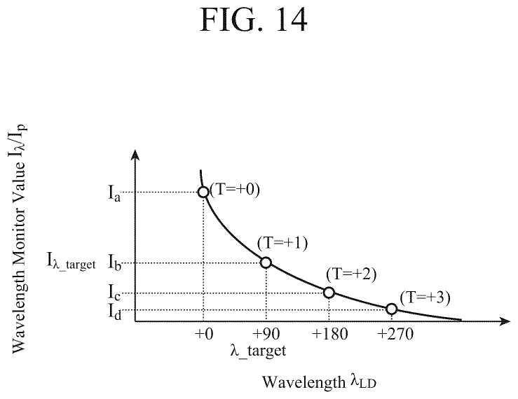

The target value Iλ_target of the wavelength monitor value Iλ/Ip is set to a region near the median value of the wavelength monitor value Iλ/Ip when the temperature of the semiconductor laser 5 and the temperature of the optical monitor 6 are changed and where the gradient of the wavelength dependence is large. For example, the target value Iλ_target is set to Iλ_target at the wavelength λLD of the laser beam of the semiconductor laser 5 illustrated in FIG. 14.

The target value Iλ_target illustrated in FIG. 14 is the wavelength monitor value Iλ/Ip indicated by Ib described in FIG. 10.

In FIG. 14, the horizontal axis represents the wavelength λLD of the laser beam of the semiconductor laser 5, and the vertical axis represents the wavelength monitor value Iλ/Ip.

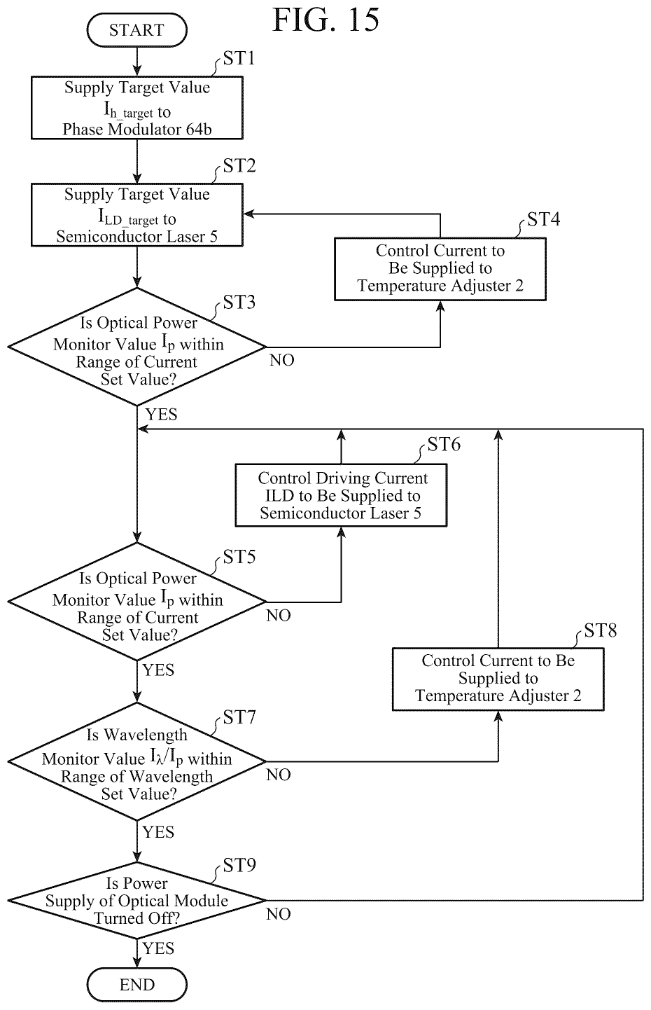

Next, the operation of the optical module will be described mainly with reference to FIG. 15.

When the optical module is activated, the controller 9 supplies the current of the target value Ih_target to the phase modulator 64b (step ST1).

When being supplied with the current of the target value Ih_target, the phase modulator 64b adjusts the position of the peak wavelength λfilt in the ring resonator filter 64a to a position prepared in advance.

Subsequently, the controller 9 supplies the driving current of the target value ILD_target to the semiconductor laser 5 (step ST2).

When the driving current of the target value ILD_target is supplied, the semiconductor laser 5 emits the forward laser beam Lf to the outside of the cap 7 through the window 8, and emits the backward laser beam Lb to the optical coupler 61 in the optical monitor 6.

The optical monitor 6 on which the backward laser beam Lb is incident monitors the light intensity and wavelength of the laser beam from the semiconductor laser 5.

That is, the laser beam from the optical coupler 61 that has received the backward laser beam Lb of the semiconductor laser 5 enters the first optical receiver 63 via the demultiplexer 62 in the optical monitor 6, is photoelectrically converted by the first optical receiver 63, and outputs a current indicating the optical power monitor value Ip to the controller 9.

Further, the laser beam from the optical coupler 61 that has received the backward laser beam Lb of the semiconductor laser 5 enters the second optical receiver 65 via the demultiplexer 62 and the optical filter 64 in the optical monitor 6, is photoelectrically converted by the second optical receiver 65, and outputs a current indicating the wavelength monitor value Iλ to the controller 9.

The controller 9 converts the optical power monitor value Ip by current into the optical power monitor value Ip by voltage, and converts the wavelength monitor value Iλ by current into the wavelength monitor value Iλ by voltage.

The conversion from the current to the voltage may be performed by the optical monitor 6.

In short, the controller 9 is only required to obtain the optical power monitor value Ip by the current or the voltage by the output from the first optical receiver 63 and obtain the wavelength monitor value Iλ by the current or the voltage by the output from the second optical receiver 65.

The controller 9 that has received the optical power monitor value Ip determines whether or not the optical power monitor value Ip is within the range of the current set value (step ST3).

The controller 9 proceeds to step ST4 when the optical power monitor value Ip is out of the range of the current set value, and proceeds to step ST5 when the optical power monitor value Ip is within the range of the current set value.

The current set value is set to, for example, ±10% of the target value Ip_target of the optical power monitor value Ip.

Step ST4 is a temperature adjusting step of a preceding stage of controlling the current supplied to the temperature adjuster 2.

Step ST4 includes a pre-stage temperature increasing step of increasing the temperature to be given to the semiconductor laser 5 and the optical monitor 6 by the temperature adjuster 2 when the optical power monitor value Ip obtained by the output from the first optical receiver 63 is larger than the current set value, and a pre-stage temperature decreasing step of decreasing the temperature to be given to the semiconductor laser 5 and the optical monitor 6 by the temperature adjuster 2 when the optical power monitor value Ip is smaller than the current set value.

When the driving current of the target value ILD_target is supplied to the semiconductor laser 5, for example, when the optical power monitor value Ip obtained from the first optical receiver 63 is larger than the current set value, the temperature of the semiconductor laser is 55° C., which is lower than the temperature indicated by the point C illustrated in FIG. 12.

When the optical power monitor value Ip obtained from the first optical receiver 63 indicates IP1, for example, the temperature of the semiconductor laser 5 is 35° C., which is the temperature indicated by the point A illustrated in FIG. 12.

Therefore, the controller 9 controls the current supplied to the temperature adjuster 2 so as to heat the mounting surface 2b of the temperature adjuster 2 with respect to the temperature adjuster 2, and returns to step ST3.

As a result, the semiconductor laser 5 and the optical monitor 6 are heated through the base 3, and the temperature of the semiconductor laser 5 and the temperature of the optical monitor 6 rise from 35° C. to 55° C.

On the other hand, when the driving current of the target value ILD_target is supplied to the semiconductor laser 5, for example, when the optical power monitor value Ip obtained from the first optical receiver 63 is smaller than the current set value, the temperature of the semiconductor laser is 55° C., which is higher than the temperature indicated by the point C illustrated in FIG. 12.

When the optical power monitor value Ip obtained from the first optical receiver 63 indicates IP2, for example, the temperature of the semiconductor laser 5 is 75° C., which is the temperature indicated by the point E illustrated in FIG. 12.

Therefore, the controller 9 controls the current supplied to the temperature adjuster 2 so as to cool the mounting surface 2b of the temperature adjuster 2 with respect to the temperature adjuster 2, and returns to step ST3.

As a result, the semiconductor laser 5 and the optical monitor 6 are cooled via the base 3, and the temperature of the semiconductor laser 5 and the temperature of the optical monitor 6 decrease from 75° C. to 55° C.

By repeating step ST4, when the temperature of the semiconductor laser 5 and the temperature of the optical monitor 6 are adjusted by the temperature adjuster 2 and fall within the range of the current set value, the controller 9 ends the temperature adjusting step of the preceding stage, and proceeds to step ST5.

The process proceeds to a wavelength locker step after step ST5.

Step ST5 is a step in which the controller 9 determines whether or not the optical power monitor value Ip is within the range of the current set value.

The controller 9 proceeds to step ST6 when the optical power monitor value Ip is out of the range of the current set value, and proceeds to step ST7 when the optical power monitor value Ip is within the range of the current set value.

Immediately after proceeding from step ST4 to step ST5, since the optical power monitor value Ip is within the range of the current set value, the process proceeds to step ST7.

Step ST7 is a step in which the controller 9 determines whether or not the wavelength monitor value Iλ/Ip is within the range of the wavelength set value.

The controller 9 proceeds to step ST8 when the wavelength monitor value Iλ/Ip is out of the range of the wavelength set value, and proceeds to step ST9 when the wavelength monitor value Iλ/Ip is within the range of the wavelength set value.

The wavelength setting value is set to, for example, +10% of the target value Iλ_target of the wavelength monitor value Iλ/Ip.

Step ST8 is a temperature adjusting step of controlling the current supplied to the temperature adjuster 2.

The temperature adjusting step is a step of adjusting the temperature to be given to the semiconductor laser 5 and the optical monitor 6 by the temperature adjuster 2 when the wavelength monitor value Iλ/Ip deviates from the wavelength set value, and in this example, includes the following temperature increasing step and temperature decreasing step.

That is, in step ST8, the controller 9 calculates the wavelength monitor value Iλ/Ip from the optical power monitor value Ip obtained by the output from the first optical receiver 63 and the wavelength monitor value Iλ obtained by the output from the second optical receiver 65, and step ST8 includes a temperature increasing step in which, when the wavelength monitor value Iλ/Ip is larger than the wavelength set value, the temperature adjuster 2 increases the temperature to be given to the semiconductor laser 5 and the optical monitor 6, and a temperature decreasing step in which when the wavelength monitor value Iλ/Ip is smaller than the wavelength set value, the temperature adjuster 2 decreases the temperature to be given to the semiconductor laser 5 and the optical monitor 6.

In the temperature increasing step, the controller 9 controls the current supplied to the temperature adjuster 2 so as to heat the mounting surface 2b of the temperature adjuster 2 with respect to the temperature adjuster 2, increases the temperature of the semiconductor laser 5 and the temperature of the optical monitor 6, increases the wavelength λLD of the laser beam from the semiconductor laser 5, reduces the wavelength monitor value Iλ/Ip as illustrated in FIG. 14, and proceeds to step ST5.

On the other hand, in the temperature decreasing step, the controller 9 controls the current supplied to the temperature adjuster 2 in such a manner as to cool the mounting surface 2b of the temperature adjuster 2 with respect to the temperature adjuster 2, decreases the temperature of the semiconductor laser 5 and the temperature of the optical monitor 6, reduces the wavelength λLD of the laser beam from the semiconductor laser 5, increases the wavelength monitor value Iλ/Ip as illustrated in FIG. 14, and proceeds to step ST5.

In the temperature increasing step in step ST8, the temperature of the semiconductor laser 5 is also increased, and as a result, the light intensity of the laser beam from the semiconductor laser 5 is reduced, and the optical power monitor value Ip is reduced.

On the other hand, in the temperature decreasing step in step ST8, the temperature of the semiconductor laser 5 is also decreased up and down, and as a result, the light intensity of the laser beam from the semiconductor laser 5 is increased and the optical power monitor value Ip is increased.

Therefore, when the temperature by the temperature adjuster 2 is adjusted in order to adjust the wavelength λLD of the laser beam from the semiconductor laser 5 in step ST8, the optical power monitor value Ip also changes, and thus, the process returns to step ST5, and in step ST5, the controller 9 determines whether or not the optical power monitor value Ip is within the range of the current set value.

In step ST5, when the optical power monitor value Ip is within the range of the current set value, the process proceeds to step ST7, and the process is repeated from step ST8 to step ST5.

On the other hand, when the optical power monitor value Ip is out of the range of the current set value in step ST5, the process proceeds to step ST6.

Step ST6 is a driving current control step of controlling the driving current to be supplied to the semiconductor laser 5.

Step ST6 includes a driving current increasing step of increasing the driving current supplied to the semiconductor laser 5 when the temperature to be given to the semiconductor laser 5 and the optical monitor 6 by the temperature adjuster 2 increases by the temperature increasing step in step ST8 and the optical power monitor value Ip obtained by the output from the first optical receiver 63 becomes smaller than the current set value, and a driving current reducing step of reducing the driving current supplied to the semiconductor laser 5 when the temperature to be given to the semiconductor laser 5 and the optical monitor 6 by the temperature adjuster 2 decreases by the temperature decreasing step in step ST8 and the optical power monitor value Ip obtained by the output from the first optical receiver 63 becomes larger than the current set value.

Therefore, the controller 9 repeats step ST6 until the optical power monitor value Ip falls within the range of the current set value, and when the optical power monitor value Ip falls within the range of the current set value, the controller 9 proceeds to step ST7, and the temperature adjusting step of controlling the current to be supplied to the temperature adjuster 2 in step ST8 is repeated.

That is, the repetition of the loop of the temperature adjusting step of step ST5-step ST7-step ST8-step ST5-step ST7 and the repetition of the loop of the driving current control step of step ST5-step ST6-step ST5 are wavelength locker steps.

By this wavelength locker step, the optical power monitor value Ip falls within the range of the current set value, and the wavelength monitor value Iλ/Ip falls within the range of the wavelength set value.

As a result, the semiconductor laser 5 enters a stable operation satisfying both of the condition that the light intensity of the laser beam from the semiconductor laser 5 is based on the target value Ip_target and the condition that the wavelength of the laser beam from the semiconductor laser 5 is based on the target value Iλ_target of the wavelength monitor value Iλ/Ip, in other words, the target value λ_target.

When the semiconductor laser 5 enters stable operation, the process proceeds to step ST9.

In step ST9, the controller 9 continues monitoring the optical power monitor value Ip and the wavelength monitor value Iλ/Ip until the optical module is powered off, and ends the wavelength locker step when the optical module is powered off.

After the semiconductor laser 5 enters stable operation, until the optical power monitor value Ip falls outside the range of the current set value or the wavelength monitor value Iλ/Ip falls outside the range of the wavelength set value, the semiconductor laser 5 operates with the driving current set by the wavelength locker step, the temperature adjuster 2 operates with the supply current set by the wavelength locker step, and the semiconductor laser 5 continues the stable operation.

When the optical power monitor value Ip falls outside the range of the current set value or the wavelength monitor value Iλ/Ip falls outside the range of the wavelength setting value, a wavelength lock function by the wavelength locker step works, and the controller 9 repeats the loop of the temperature adjusting step of step ST5-step ST7-step ST8-step ST5-step ST7 and repeats the loop of the driving current control step of step ST5-step ST6-step ST5.

As a result, the semiconductor laser 5 again enters stable operation satisfying both of the condition that the light intensity of the laser beam from the semiconductor laser 5 is based on the target value Ip_target and the condition that the wavelength of the laser beam from the semiconductor laser 5 is based on the target value Iλ_target of the wavelength monitor value Iλ/Ip.

As described above, the optical module according to the first embodiment includes the optical monitor 6 including the first optical receiver 63 to receive a laser beam from the semiconductor laser 5, the optical filter 64 to receive a laser beam from the semiconductor laser 5, and the second optical receiver 65 to receive the laser beam via the optical filter 64, and the temperature adjuster 2 to adjust a temperature in the semiconductor laser 5 and a temperature in the optical monitor 6, and to perform control to increase a temperature to be given to the semiconductor laser 5 and the optical monitor 6 when the wavelength monitor value Iλ/Ip, which is a ratio between the optical power monitor value Ip obtained by an output from the first optical receiver 63 and the wavelength monitor value Iλ obtained by an output from the second optical receiver 65, is larger than the wavelength set value, and decrease the temperature to be given to the semiconductor laser 5 and the optical monitor 6 when the wavelength monitor value Iλ/Ip is smaller than the wavelength set value, so that precise control can be performed for a single wavelength, the number of components is small, and downsizing can be achieved.

In the optical module according to the first embodiment, the temperature adjuster 2 performs control to increase the temperature to be given to the semiconductor laser 5 and the optical monitor 6 when the wavelength monitor value Iλ/Ip is larger than the wavelength set value, increase the driving current to be supplied to the semiconductor laser 5 when the optical power monitor value Ip becomes smaller than the current set value, decrease the temperature to be given to the semiconductor laser 5 and the optical monitor 6 when the wavelength monitor value Iλ/Ip is smaller than the wavelength set value, and reduce the driving current to be supplied to the semiconductor laser 5 when the optical power monitor value Ip is larger than the current set value, so that more precise control can be performed.

The optical module according to the first embodiment includes the base 3 that includes the elevation surface portion 3b and the flat surface portion 3a that are formed integrally, and the flat surface portion 3a is fixed to the mounting surface 1a of the stem 1, in which the semiconductor laser 5 is mounted and fixed on the elevation surface portion 3b of the base 3, and the optical monitor 6 is mounted and fixed at a position of the flat surface portion 3a of the base 3 where the backward laser beam of the semiconductor laser 5 is received, so that the optical module can be further downsized.

In the optical module according to the first embodiment, since the semiconductor laser 5, the optical monitor 6, the temperature adjuster 2, and the base 3 are disposed in the space formed by the stem 1 and the cap 7, the number of lead pins for the semiconductor laser 5, the optical monitor 6, and the temperature adjuster 2 can be reduced.

### Modification of First Embodiment

Note that, in the first embodiment described above, the temperature dependence of the wavelength in the single-wavelength semiconductor laser 5 is set to 90 pm/° C., the temperature dependence of the peak value of the wavelength in the ring resonator filter 64a is set to 70 pm/° C., and as illustrated in FIGS. 9 and 10, the phase is adjusted in such a manner that the wavelength λLD in the semiconductor laser 5 comes to the right of the peak value of the wavelength in the ring resonator filter 64a, and the temperature is increased with respect to the wavelength λLD of the laser beam of the semiconductor laser, whereby the wavelength monitor value Iλ/Ip has a downward gradient to the right.

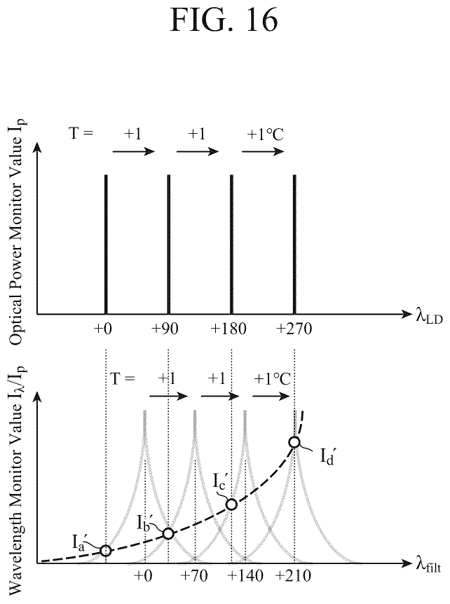

On the other hand, as illustrated in FIG. 16, the phase may be adjusted in such a manner that the wavelength λLD in the semiconductor laser 5 comes to the left side of the peak value of the wavelength in the ring resonator filter 64a, and the temperature may be increased with respect to the wavelength λLD of the laser beam of the semiconductor laser, so that the wavelength monitor value Iλ/Ip has a gradient of rising to the right, in other words, falling to the left.

That is, every time the temperature in the semiconductor laser 5 and the ring resonator filter 64a increases by +1° C., the wavelength monitor value Iλ/Ip changes as Ib′, Ic′, and Id′ in order from Ia′ indicated by a circle in FIG. 16.

In the case of the modification of the first embodiment, control to change, by the temperature adjuster 2, the temperature of the mounting surface 2b in accordance with the value of the supplied current when the wavelength monitor value Iλ/Ip deviates from the wavelength set value and change the temperature to be given to the semiconductor laser 5 and the optical monitor 6 is as follows.

That is, when the wavelength monitor value Iλ/Ip is larger than the wavelength set value, the temperature adjuster 2 cools the mounting surface 2b in accordance with the value of the supplied current to lower the temperature to be given to the semiconductor laser 5 and the optical monitor 6.

When the wavelength monitor value Iλ/Ip is smaller than the wavelength set value, the temperature adjuster 2 heats the mounting surface 2b in accordance with the value of the supplied current to increase the temperature to be given to the semiconductor laser 5 and the optical monitor 6.

Further, by decreasing the temperature to be given to the semiconductor laser 5 and the optical monitor 6 by the temperature adjuster 2, when the optical power monitor value Ip obtained by the output from the first optical receiver 63 becomes larger than the current set value, the driving current supplied to the semiconductor laser 5 is reduced.

When the temperature adjuster 2 increases the temperature to be given to the semiconductor laser 5 and the optical monitor 6, and the optical power monitor value Ip obtained by the output from the first optical receiver 63 becomes smaller than the current set value, the driving current supplied to the semiconductor laser 5 is increased.

On the other hand, when the wavelength monitor value Iλ/Ip deviates from the wavelength set value, the temperature adjusting step (step ST8) of adjusting the temperature to be given to the semiconductor laser and the optical monitor by the temperature adjuster includes the following temperature increasing step and temperature decreasing step.

In the temperature increasing step, when the wavelength monitor value Iλ/Ip is larger than the wavelength set value, the temperature adjuster 2 increases the temperature to be given to the semiconductor laser 5 and the optical monitor 6.

In the temperature decreasing step, when the wavelength monitor value Iλ/Ip is smaller than the wavelength set value, the temperature adjuster 2 decreases the temperature to be given to the semiconductor laser 5 and the optical monitor 6.

Further, the driving current control step (step ST6) includes the following driving current increasing step and driving current reducing step.

In the driving current increasing step, when the temperature to be given to the semiconductor laser 5 and the optical monitor 6 is increased by the temperature adjuster 2 by the temperature increasing step, and the optical power monitor value Ip obtained by the output from the first optical receiver 63 becomes smaller than the current set value, the driving current to be supplied to the semiconductor laser 5 is increased.

In the driving current reducing step, when the temperature to be given to the semiconductor laser 5 and the optical monitor 6 is decreased by the temperature adjuster 2 by the temperature decreasing step and the optical power monitor value Ip obtained by the output from the first optical receiver 63 becomes larger than the current set value, the driving current supplied to the semiconductor laser 5 is reduced.

The optical module according to the modification of the first embodiment configured as described above also has an effect similar to that of the optical module according to the first embodiment.

Note that the optical module according to the modification of the first embodiment also has a configuration similar to that of the optical module according to the first embodiment except for a difference in the relationship between the temperature dependence of the wavelength in the semiconductor laser 5 and the temperature dependence of the peak value of the wavelength in the ring resonator filter 64a.

### Second Embodiment

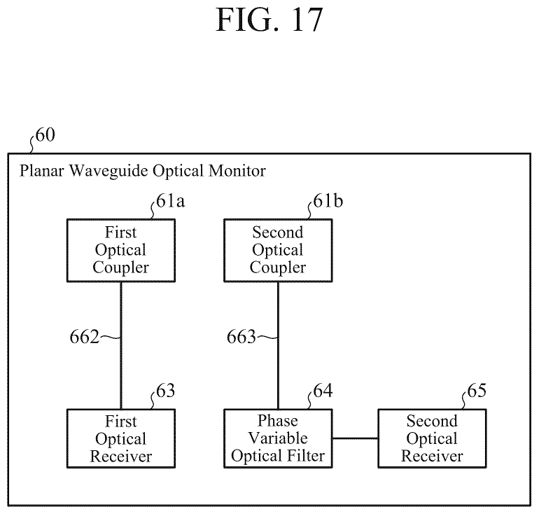

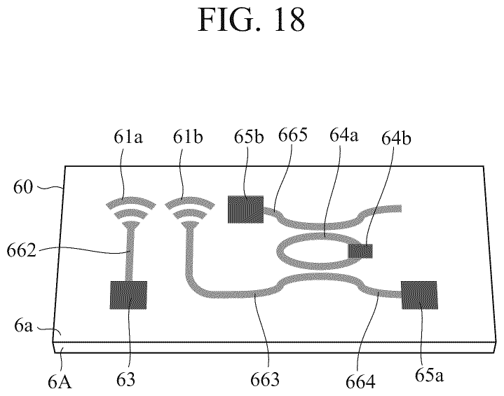

An optical module according to the second embodiment will be described with reference to FIGS. 17 and 18.

The optical module according to the second embodiment is different from the optical module according to the first embodiment in configuration of the optical monitor 6, and is the same as or similar to the optical module according to the first embodiment in other points.

That is, while the optical monitor 6 in the optical module according to the first embodiment is the laser beam obtained by demultiplexing the backward laser beam Lb of the semiconductor laser 5 incident on each of the first optical receiver 63 and the second optical receiver 65 by the demultiplexer 62, an optical monitor 60 in the optical module according to the second embodiment is a laser beam received by a first optical coupler 61a and a second optical coupler 61b provided corresponding to the backward laser beam Lb of the semiconductor laser 5 incident on each of a first optical receiver 63 and a second optical receiver 65.

Note that, in FIGS. 17 and 18, the same reference numerals as those attached in FIGS. 1 to 16 denote the same or corresponding parts.

The optical monitor 60 includes the first optical coupler 61a, the second optical coupler 61b, the first optical receiver 63, an optical filter 64, the second optical receiver 65, and optical waveguides 662 to 665.

The optical monitor 60 is, for example, a planar waveguide optical monitor using a silicon photonics chip formed by integrating the first optical coupler 61a, the second optical coupler 61b, the first optical receiver 63, the optical filter 64, the second optical receiver 65, and the optical waveguides 662 to 665 on a flat surface of a silicon (Si) substrate 6A.

The first optical coupler 61a receives the backward laser beam Lb from the semiconductor laser 5, and couples the backward laser beam Lb incident perpendicularly to the flat surface 6a of the optical monitor 60 to the optical waveguide 662.

The first optical receiver 63 receives the backward laser beam Lb via the optical waveguide 662, photoelectrically converts the backward laser beam Lb, and outputs an optical power monitor value Ip indicating the light intensity of the laser beam from the semiconductor laser 5 by a current value.

The second optical coupler 61b receives the backward laser beam Lb from the semiconductor laser 5, and couples the backward laser beam Lb incident perpendicularly to the flat surface 6a of the optical monitor 60 to the optical waveguide 663.

The optical filter 64 receives the backward laser beam Lb via the optical waveguide 663.

The second optical receiver 65 using either the photodiode 65a or the photodiode 65b coupled to the optical filter 64 receives the backward laser beam Lb via the optical filter 64, performs photoelectric conversion, and outputs a wavelength monitor value Iλ used to obtain a wavelength monitor value Iλ/Ip of the semiconductor laser 5 for monitoring the wavelength λLD of the laser beam from the semiconductor laser 5.

That is, the optical monitor 60 in the optical module according to the second embodiment has a function similar to that of the optical monitor 6 in the optical module according to the first embodiment, and receives the backward laser beam Lb from the semiconductor laser 5 to obtain the optical power monitor value Ip and the wavelength monitor value Iλ having the same value.

The first optical coupler 61a and the second optical coupler 61b are, for example, grating couplers and may be elephant couplers.

Note that the modification described for the optical monitor 6 in the optical module according to the first embodiment can also be applied to the optical monitor 60 in the optical module according to the second embodiment.

In the operation of the optical module according to the second embodiment, the optical monitor 60 in the optical module according to the second embodiment has a function similar to that of the optical monitor 6 in the optical module according to the first embodiment, and the optical power monitor value Ip and the wavelength monitor value Iλ having the same value are obtained, so that the same operation as that of the optical module according to the first embodiment is performed, and the description thereof is omitted.

As described above, the optical module according to the second embodiment also has an effect similar to the optical module according to the first embodiment. Third Embodiment.

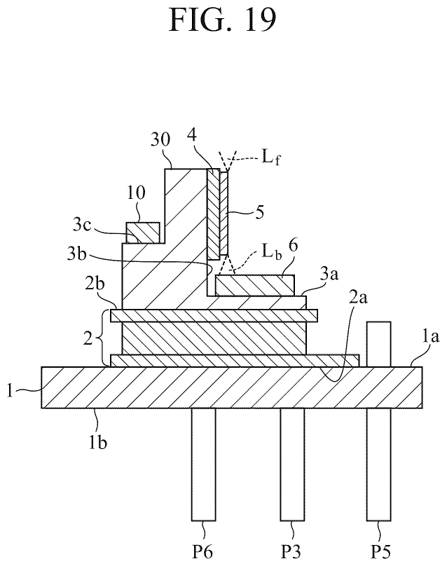

An optical module according to a third embodiment will be described with reference to FIG. 19.

The optical module according to the third embodiment is different from the optical module according to the first embodiment in that a thermistor 10 is added, and the other points are the same or similar.

Note that, in FIG. 19, the same reference numerals as those attached in FIGS. 1 to 16 denote the same or corresponding parts.

Similarly to the base 3 in the optical module according to the first embodiment, a base 30 is an L-shaped metal member including a flat surface portion 3a having upper and lower surfaces that are flat surfaces, and an elevation surface portion 3b formed integrally with the flat surface portion 3a and having an elevation surface that is a flat surface, and a stepped portion having a mounting surface 3c that is a horizontal surface on which the thermistor 10 is mounted and fixed is formed on the opposite side of the elevation surface portion 3b on which the semiconductor laser 5 is mounted and fixed.

The thermistor 10 is mounted and fixed on the mounting surface 3c of the base 30, and detects the temperature of the base 30, that is, the temperature of the semiconductor laser 5 and the temperature of the optical monitor 6.

In the preliminary preparation described in the optical module according to the first embodiment, the thermistor 10 detects the temperature of the semiconductor laser 5 and the temperature of the optical monitor 6, so that the relationship between the target value λ_target of the wavelength λLD, the target value Ip_target of the optical power monitor value Ip, the temperature of the semiconductor laser 5, and the temperature of the optical monitor 6 can be known with higher accuracy.

The other components and the operation in the optical module according to the third embodiment are the same as the other components and the operation in the optical module according to the first embodiment, and thus the description thereof will be omitted.

Note that free combinations of the embodiments, modifications of any component of each embodiment, or omissions of any component in each embodiment are possible.

### INDUSTRIAL APPLICABILITY

The optical module according to the present disclosure is preferable for an optical module used in a large-capacity optical communication system, particularly, an optical module used in a digital coherent communication method.

### REFERENCE SIGNS LIST

1: stem, 2: temperature adjuster, 3, 30: base, 4: semiconductor laser submount, 5: semiconductor laser, 6, 60: planar waveguide optical monitor, 61: optical coupler, 62: demultiplexer, 63: first optical receiver, 64: optical filter, 65: second optical receiver, 7: cap, 8: window, 9: controller, P1 to P5: lead pin.

1. An optical module comprising:
a semiconductor laser;
an optical monitor including a first optical receiver to receive a laser beam from the semiconductor laser, an optical filter to receive the laser beam from the semiconductor laser, and a second optical receiver to receive the laser beam via the optical filter;
a stem on which a temperature adjuster is mounted, the temperature adjuster is configured to adjust a temperature in the semiconductor laser and a temperature in the optical monitor, and to perform control, when a wavelength monitor value Iλ/Ip, which is a ratio between an optical power monitor value Ip obtained by an output from the first optical receiver and a wavelength monitor value Iλ obtained by an output from the second optical receiver, deviates from a wavelength set value, to change a temperature to be given to the semiconductor laser and the optical monitor;
a base that is mounted and fixed on a mounting surface of the temperature adjuster mounted on the stem and includes an elevation surface portion on which the semiconductor laser is mounted and fixed, and a flat surface portion that is formed integrally with the elevation surface portion and on which the optical monitor is mounted and fixed at a position where a backward laser beam of the semiconductor laser is received; and
a cylindrical cap having a bottomed portion and a side wall portion, the bottomed portion having a window through which a forward laser beam of the semiconductor laser is emitted, the cap covering an inner flat surface side of the stem, and having an open end surface of the side wall portion fixed in contact with a peripheral end portion of the inner flat surface of the stem.

2. The optical module according to claim 1, wherein the control to change the temperature to be given to the semiconductor laser and the optical monitor when the wavelength monitor value Iλ/Ip deviates from the wavelength set value is control to increase the temperature to be given to the semiconductor laser and the optical monitor when the wavelength monitor value Iλ/Ip is larger than the wavelength set value, and decrease the temperature to be given to the semiconductor laser and the optical monitor when the wavelength monitor value Iλ/Ip is smaller than the wavelength set value.

3. The optical module according to claim 1, wherein
the control to change the temperature to be given to the semiconductor laser and the optical monitor when the wavelength monitor value Iλ/Ip deviates from the wavelength set value is control to increase the temperature to be given to the semiconductor laser and the optical monitor when the wavelength monitor value Iλ/Ip is larger than the wavelength set value, and decrease the temperature to be given to the semiconductor laser and the optical monitor when the wavelength monitor value Iλ/Ip is smaller than the wavelength set value, and
the temperature adjuster performs control to increase a driving current to be supplied to the semiconductor laser when the optical power monitor value Ip becomes smaller than the current set value by increasing the temperature to be given to the semiconductor laser and the optical monitor when the wavelength monitor value Iλ/Ip is larger than the wavelength set value, and performs control to reduce a driving current to be supplied to the semiconductor laser when the optical power monitor value Ip becomes larger than the current set value by decreasing the temperature to be given to the semiconductor laser and the optical monitor when the wavelength monitor value Iλ/Ip is smaller than the wavelength set value.

4. The optical module according to claim 1, wherein the control to change the temperature to be given to the semiconductor laser and the optical monitor when the wavelength monitor value Iλ/Ip deviates from the wavelength set value is control to decrease the temperature to be given to the semiconductor laser and the optical monitor when the wavelength monitor value Iλ/Ip is larger than the wavelength set value, and to increase the temperature to be given to the semiconductor laser and the optical monitor when the wavelength monitor value Iλ/Ip is smaller than the wavelength set value.

5. The optical module according to claim 1, wherein
the control to change the temperature to be given to the semiconductor laser and the optical monitor when the wavelength monitor value Iλ/Ip deviates from the wavelength set value is control to decrease the temperature to be given to the semiconductor laser and the optical monitor when the wavelength monitor value Iλ/Ip is larger than the wavelength set value and to increase the temperature to be given to the semiconductor laser and the optical monitor when the wavelength monitor value Iλ/Ip is smaller than the wavelength set value, and
the temperature adjuster performs control to reduce a driving current to be supplied to the semiconductor laser when the optical power monitor value Ip becomes larger than the current set value by decreasing the temperature to be given to the semiconductor laser and the optical monitor when the wavelength monitor value Iλ/Ip is larger than the wavelength set value, and performs control to increase a driving current to be supplied to the semiconductor laser when the optical power monitor value Ip becomes smaller than the current set value by increasing the temperature to be given to the semiconductor laser and the optical monitor when the wavelength monitor value Iλ/Ip is smaller than the wavelength set value.

6. The optical module according to claim 1, wherein the semiconductor laser is a single mode laser oscillating at a single wavelength.

7. The optical module according to claim 1, wherein the optical filter is a phase variable optical filter having temperature dependence of a wavelength.

8. The optical module according to claim 1, wherein the temperature adjuster further performs control to increase the temperature to be given to the semiconductor laser and the optical monitor when a current value Ip of a current obtained by the first optical receiver is larger than a current set value, and to decrease the temperature to be given to the semiconductor laser and the optical monitor when the current value Ip is smaller than the current set value.

9-22. (canceled)

23. The optical module according to claim 1, further comprising:
a main signal lead pin penetrating the stem and having an inner lead part exposed from the inner flat surface of the stem to which an electrode of the semiconductor laser is connected;
a first monitor lead pin penetrating the stem and having an inner lead part exposed from the inner flat surface of the stem to which the first optical receiver of the optical monitor is connected;
a second monitor lead pin penetrating the stem and having an inner lead part exposed from the inner flat surface of the stem to which the second optical receiver of the optical monitor is connected; and
a pair of temperature control lead pins penetrating the stem and having an inner lead part exposed from the inner flat surface of the stem to which a pair of electrodes in the temperature adjuster is connected.

24. The optical module according to claim 1, wherein
the optical filter in the optical monitor includes a ring resonator filter and a phase modulator, and
the optical module further comprises:
a main signal lead pin penetrating the stem and having an inner lead part exposed from the inner flat surface of the stem to which an electrode of the semiconductor laser is connected;
a first monitor lead pin penetrating the stem and having an inner lead part exposed from the inner flat surface of the stem to which the first optical receiver of the optical monitor is connected;
a second monitor lead pin penetrating the stem and having an inner lead part exposed from the inner flat surface of the stem to which the second optical receiver of the optical monitor is connected;
a pair of temperature control lead pins penetrating the stem and having an inner lead part exposed from the inner flat surface of the stem to which a pair of electrodes in the temperature adjuster is connected; and
a phase adjusting lead pin penetrating the stem and having an inner lead part exposed from the inner flat surface of the stem to which the phase modulator is connected.

25. The optical module according to claim 1, wherein
the optical monitor is a planar waveguide optical monitor in which the first optical receiver, the optical filter, and the second optical receiver are integrated,
the planar waveguide optical monitor further includes an optical coupler to receive a laser beam from the semiconductor laser and a demultiplexer to demultiplex the laser beam received by the optical coupler into two laser beams,
the laser beam received by the first optical receiver is one of the two laser beams demultiplexed from the demultiplexer, and
the laser beam received by the optical filter is another one of the two laser beams demultiplexed from the demultiplexer.

26. The optical module according to claim 25, wherein
the planar waveguide optical monitor is implemented by using a silicon photonics chip formed by integrating the optical coupler, the demultiplexer, the first optical receiver, the optical filter, and the second optical receiver on a flat surface of a silicon substrate, and
the optical coupler is a grating coupler.

27. The optical module according to claim 1, wherein
the optical monitor is a planar waveguide optical monitor in which the first optical receiver, the optical filter, and the second optical receiver are integrated,
the planar waveguide optical monitor further includes a first optical coupler to receive a laser beam from the semiconductor laser and a second optical coupler to receive a laser beam from the semiconductor laser,
the laser beam received by the first optical receiver is a laser beam from the first optical coupler, and
the laser beam received by the optical filter is a laser beam from the second optical coupler.

28. The optical module according to claim 27, wherein
the planar waveguide optical monitor is implemented by using a silicon photonics chip formed by integrating the first optical coupler, the second optical coupler, the first optical receiver, the optical filter, and the second optical receiver on a flat surface of a silicon substrate, and
each of the first optical coupler and the second optical coupler is a grating coupler.
